(19) United States
(12) Patent Application Publication
(10) Pub. No.: US 2024/0224665 A1
(43) Pub. Date: Jul. 4, 2024

(54) ARRAY SUBSTRATE INCLUDING OXIDE SEMICONDUCTOR PATTERN AND DISPLAY DEVICE INCLUDING THE SAME

(71) Applicant: LG Display Co., Ltd., Seoul (KR)

(72) Inventor: Jang-Dae KIM, Paju-si (KR)

(73) Assignee: LG Display Co., Ltd., Seoul (KR)

(21) Appl. No.: 18/523,471

(22) Filed: Nov. 29, 2023

(30) Foreign Application Priority Data
Jan. 2, 2023 (KR) 10-2023-0000212

(51) Int. Cl. H10K 59/131; H10K 59/121

(52) U.S. Cl. CPC H10K 59/131; H10K 59/1213

(57) ABSTRACT

A display device can a display area and a non-display area adjacent to the display area disposed on a substrate, and a first thin film transistor disposed in the display area and including a first semiconductor pattern, a first gate electrode, a first source electrode and a first drain electrode. The display device further includes an emitting element disposed in the display area and connected to the first thin film transistor, and a first lower conductive pattern disposed under the first semiconductor pattern. The first lower conductive pattern can overlap with the first semiconductor pattern and has at least one uneven pattern on a top surface thereof. Further, the first lower conductive pattern is connected to one of the first source electrode and the first drain electrode.

### CROSS REFERENCE TO RELATED APPLICATIONS

The present application claims priority to Korean Patent Application No. 10-2023-0000212, filed in the Republic of Korea on Jan. 2, 2023, the entire disclosure of which is hereby expressly incorporated by reference into the present application.

### BACKGROUND

### Technical Field

The present disclosure relates to an array substrate for a display device, and more particularly, to an array substrate and a display device including the array substrate, where a thin film transistor of the array substrate can display a relatively low gray level, a leakage current of the thin film transistor is blocked or minimized, and a threshold voltage of the thin film transistor is increased.

### DISCUSSION OF THE RELATED ART

As the use and applications for multimedia communication increase, an importance and need for improved flat panel displays have increased. Flat panel displays are used in different fields of technologies, including but not limited to, in the fields of televisions, computers, smart phones, navigation devices, extended reality (XR) devices, augmented reality (AR) devices, theater systems, steaming system, gaming systems, wearable devices, etc.

Among various flat panel displays (FPDs), a liquid crystal display (LCD) device, a plasma display panel (PDP) and an organic light emitting diode (OLED) display device have been utilized. Further, among the various flat panel displays, the OLED display device has been widely used because of its advantages such as a relatively high response speed, a relatively high luminance and a relatively wide viewing angle.

In the OLED display device, a plurality of pixels are arranged in a matrix shape, and each pixel can be composed of multiple subpixels. Each pixel or subpixel can include an emitting element part having an emitting layer and a pixel circuit part having a plurality of thin film transistors (TFTs). The pixel circuit part includes a driving TFT for driving an emitting element by supplying a driving current thereto and a switching TFT for supplying a gate signal to the driving TFT. Further, a gate driving unit for supplying the gate signal to the pixel is disposed in a non-display area of the OLED display device.

Although the TFTs in the pixel circuit parts of the OLED display device generally perform well, the TFT in the pixel circuit part of some subpixels can have a leakage current in an off state and a displaying in a relatively low gray level range can be affected or deteriorated due to the leakage current, which in turn can lower the displaying quality of the OLED display device.

### SUMMARY OF THE DISCLOSURE

Accordingly, embodiments of the present disclosure are directed to an array substrate including a thin film transistor and a display device including the array substrate that substantially obviates one or more of problems due to the limitations and disadvantages of the related art.

An object of the present disclosure is to provide an array substrate and a display device including the array substrate, where a leakage current of a thin film transistor in a pixel circuit part of each of one or more subpixels is blocked and a relatively low gray level range is displayed well by the display device.

Another object of the present disclosure is to provide an array substrate and a display device including the array substrate, where a leakage current of a thin film transistor using an oxide semiconductor pattern having a relatively high s-factor as an active layer is blocked, a relatively low gray level is displayed well, and a threshold voltage of the thin film transistor is equal to or higher than a target value.

Additional features and advantages of the disclosure will be set forth in the description which follows, and in part will be apparent to those skilled in the art from the description or can be learned by practice of the disclosure. These and other advantages of the disclosure can be realized and attained by the structure particularly pointed out in, or derivable from, the written description, claims hereof, and the appended drawings.

Embodiments described herein relate to display devices that achieve the above-described advantages. In one embodiment, a display device includes a substrate having a display area and a non-display area at a periphery of the display area; a first thin film transistor in the display area, the first thin film transistor including a first semiconductor pattern, a first gate electrode, a first source electrode and a first drain electrode; an emitting element in the display area, the emitting element connected to the first thin film transistor; and a first lower conductive pattern under the first semiconductor pattern, the first lower conductive pattern overlapping with the first semiconductor pattern and having a plurality of uneven patterns on a top surface thereof, wherein the first lower conductive pattern is connected to one of the first source electrode and the first drain electrode.

In one embodiment, an array substrate for a display device includes a substrate having a display area and a non-display area at a periphery of the display area; a buffer layer on the substrate; a first semiconductor pattern on the buffer layer; a first gate electrode over the first semiconductor pattern, the first gate electrode overlapping the first semiconductor pattern; a first source electrode and a first drain electrode over the first semiconductor pattern, the first source electrode and the first drain electrode electrically connected to the first semiconductor pattern; and a lower conductive pattern under the first semiconductor pattern, the buffer layer disposed between the lower conductive pattern and the first semiconductor pattern and the lower conductive pattern having a plurality of uneven patterns on a top surface thereof, wherein the lower conductive pattern is electrically connected to the first semiconductor pattern.

It is to be understood that both the foregoing general description and the following detailed description are explanatory and by way of examples and are intended to provide further explanation of the disclosure as claimed without limiting its scope.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing a display device according to a first embodiment of the present disclosure;

FIG. 2 is a view showing a subpixel of the display device according to the first embodiment of the present disclosure;

FIG. 3 is a view showing a pixel circuit of the subpixel of the display device according to the first embodiment of the present disclosure;

FIG. 4 is an example of a cross-sectional view showing the display device according to the first embodiment of the present disclosure;

FIG. 5A is a plan view showing a driving thin film transistor of the display device according to the first embodiment of the present disclosure;

FIGS. 5B to 5D are plan views showing material layers of the driving thin film transistor of FIG. 5A;

FIG. 6A is a cross-sectional view taken along a line I-I′ of FIG. 5A;

FIG. 6B is a circuit diagram showing an example of the parasitic capacitances of the driving thin film transistor of FIG. 6A;

FIG. 7 is a cross-sectional view showing a driving thin film transistor of a display device according to a second embodiment of the present disclosure; and

FIG. 8 is a cross-sectional view showing a switching thin film transistor of a display device according to a third embodiment of the present disclosure.

### DETAILED DESCRIPTION OF THE EMBODIMENTS

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration can unnecessarily obscure a feature or aspect of the present disclosure, a detailed description of such known function or configuration can be omitted or a brief description can be provided. Further, the term “exemplary” or “exemplarily” is used to mean an example, and is interchangeably used with the term “example”. Further, embodiments are example embodiments and aspects are example aspects. Any implementation described herein as an “exemplary” (or “exemplarily”) or “example” is not necessarily to be construed as preferred or advantageous over other implementations.

Where the terms “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” or “over” another element or layer, a third layer or element or multiple elements/layers can be interposed therebetween.

Although the terms “first,” “second,” A, B, (a), (b), and the like can be used herein to refer to various elements, these elements should not be interpreted to be limited by these terms as they are not used to define a particular order or precedence. These terms are only used to distinguish one element from another and may not define order or sequence. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” can include all combinations of two or more of the first, second and third elements as well as the first, second or third element.

The term “display device” (or display apparatus) can include a display device in a narrow sense such as a liquid crystal module (LCM), an organic light emitting diode (OLED) module and a quantum dot (QD) module including a display panel and a driving unit for driving the display panel. In addition, the term “display device” (or display apparatus) can include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure can include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit can be expressed as “a display device”, and an electronic apparatus of a complete product including the LCM, the OLED module and the QD module can be expressed as “a set device.” For example, a display device in a narrow sense can include a display panel of a liquid crystal, an organic light emitting diode and a quantum dot and a source printed circuit board (PCB) of a control unit for driving the display panel, and a set device can further include a set PCB of a set control unit electrically connected to the source PCB for controlling the entire set device.

The display panel of the present disclosure can include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel can include a plurality of gate lines, a plurality of data lines and a plurality of subpixels in crossing regions of the plurality of gate lines and the plurality of data lines. The display panel can include an array having a thin film transistor of an element for selectively applying a voltage to each subpixel, an emitting element layer on the array and an encapsulating substrate or an encapsulation part covering the emitting element layer. The encapsulation part can protect the thin film transistor(s) and the emitting element layer(s) from an external impact and can prevent or at least reduce penetration of a moisture or an oxygen into the emitting element layer(s). In addition, a layer on the array can include an inorganic light emitting layer, for example, a nano-sized material layer or a quantum dot.

Features of various embodiments of the present disclosure can be partially or entirely coupled to or combined with each other. They can be linked and operated technically in various ways as those skilled in the art can sufficiently understand. The embodiments can be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

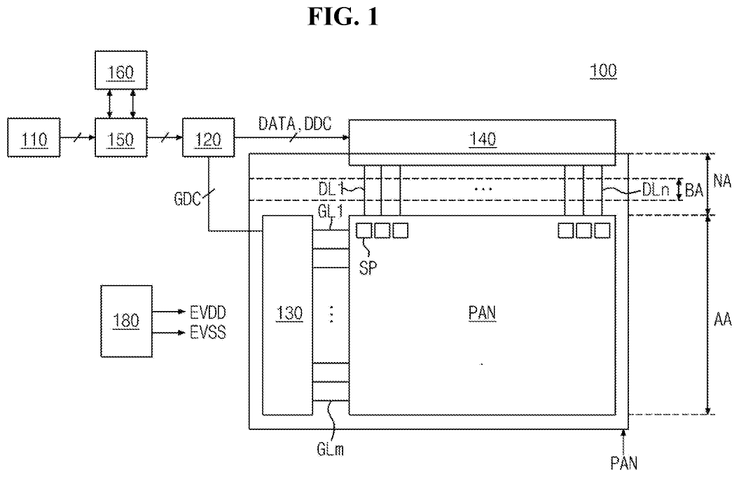

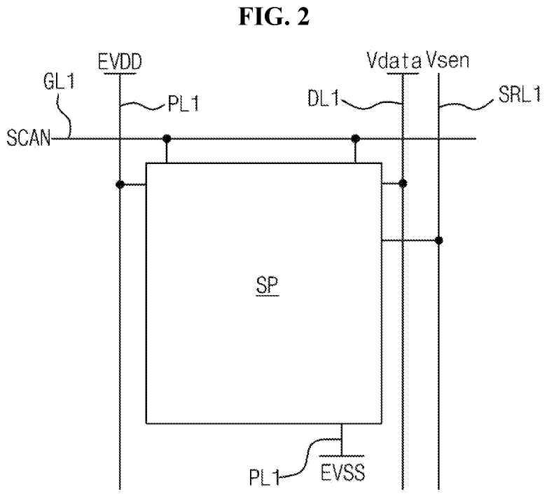

FIG. 1 is a view showing a display device according to a first embodiment of the present disclosure, and FIG. 2 is a view showing a subpixel of the display device according to the first embodiment of the present disclosure.

Referring to FIG. 1, a display device 100 according to the first embodiment of the present disclosure can include an image processing unit 110, a deterioration compensating unit 150, a memory 160, a timing controlling unit 120, a data driving unit 140, a power supplying unit 180, a gate driving unit 130 and a display panel PAN. The gate driving unit 130 is disposed in the display panel PAN. The display panel PAN includes a display area (active area) AA and a non-display area (non-active area) NA at a periphery of the display area AA, and the non-display area NA includes a bending area BA. The display panel PAN can be folded at the bending area BA so that a bezel can be reduced. As variations, the non-display area NA can surround the display area AA completely or only in part. The non-display area NA can be disposed at multiple sides of the display area AA, and the non-display area NA at multiple sides can include one or more bending areas BA. The display panel PAN includes a plurality of subpixels SP arranged in a matrix configuration or other configurations.

The image processing unit 110 outputs an image data supplied from an exterior (e.g., another electronic device, user input, etc.) and a driving signal for driving various elements.

The deterioration compensating unit 150 modulates the image data of each subpixel SP of the present frame based on a sensing voltage Vsen supplied from the data driving unit 140 and supplies the modulated image data to the timing controlling unit 120.

The timing controlling unit 120 generates and outputs a gate control signal GDC for controlling an operation timing of the gate driving unit 130 and a data control signal DDC along with the modulated image data DATA for controlling an operation timing of the data driving unit 140 based on the driving signal inputted from the image processing unit 110.

The gate driving unit 130 outputs a gate signal to the display panel PAN in response to the gate control signal GDC supplied from the timing controlling unit 120. The gate driving unit 130 outputs the gate signal to a plurality of gate lines GL1 to GLm where m can be a positive number such as a positive integer greater than 1. As an example, the gate driving unit 130 can have a gate-in-panel (GIP) type where thin film transistors are disposed on a substrate having a plurality of pixels. The GIP type gate driving unit 130 can include a plurality of circuits such as a shift register and a level shifter.

The data driving unit 140 outputs a data voltage to the display panel PAN in response to the data control signal DDC supplied from the timing controlling unit 120. The data driving unit 140 outputs the data voltage to a plurality of data lines DL1 to DLn where n can be a positive number such as a positive integer greater than 1.

The power supplying unit 180 outputs a high level voltage EVDD and a low level voltage EVSS to the display panel PAN. The high level voltage EVDD and the low level voltage EVSS are supplied to the display panel PAN through one or more power lines.

The display panel PAN displays an image in response to the data voltage of the data driving unit 140, the gate signal of the gate driving unit 130 in the non-display area NA and the power of the power supplying unit 180.

The plurality of subpixels SP are disposed in the display area AA of the display panel PAN to display an image. The plurality of subpixels SP can include a red subpixel, a green subpixel and a blue subpixel, or a white subpixel, a red subpixel, a green subpixel and a blue subpixel, but other variations are possible. The white, red, green and blue subpixels can have the same area as each other, or can have different areas from each other. For instance, the different color subpixels can have the same shape and/or area size, or can have different shapes and/or are sizes.

The memory 160 stores a deterioration compensating timing of the emitting element in each subpixel SP as well as a lookup table on a deterioration compensating gain. The deterioration compensating timing of the emitting element can be a driving number or a driving time of the display panel PAN.

Referring to FIG. 2 which illustrates an example of one subpixel P of FIG. 1, the subpixel SP can be connected to a gate line GL1 (for supplying a scan or gate signal), a data line DL1, a sensing voltage readout line SRL1 and a power line PL1 (e.g., for supplying the high level voltage EVDD and/or the low level voltage EVSS). The number of the transistors and the capacitors and a driving method of the subpixel SP can be determined according to a structure of the circuit. Each or some of the subpixels SP in the display panel PAN can have the configuration shown in FIG. 2, but can have other circuit configurations.

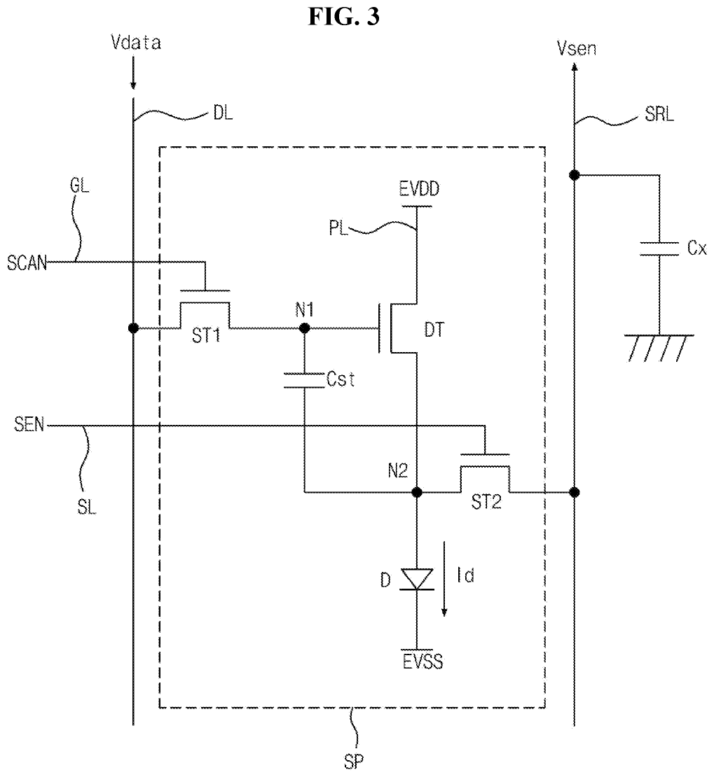

FIG. 3 is a view showing an example of a pixel circuit of a subpixel of the display device according to the first embodiment of the present disclosure.

Referring to FIG. 3, the display device 100 includes a gate line GL, a data line DL, a power line PL and a sensing line SL crossing each other to define the subpixel SP. The subpixel SP includes a driving thin film transistor (TFT) DT, an emitting element D, a storage capacitor Cst, a first switching TFT ST1 and a second switching TFT ST2.

The emitting element D can be a light emitting diode including an anode connected to a second node N2, a cathode connected to a low level voltage EVSS and an emitting layer between the anode and the cathode.

The driving TFT DT adjusts a current Id flowing through the emitting element D according to a gate-source voltage Vgs. The driving TFT DT includes a gate electrode connected to a first node N1, a drain electrode connected to a high level voltage EVDD of the power line PL and a source electrode connected to the second node N2.

The storage capacitor Cst is connected between the first node N1 and the second node N2.

When the display panel PAN is driven, the first switching TFT ST1 applies the data voltage Vdata of the data line DL to the first node N1 in response to the gate signal SCAN of the gate line GL to turn on the driving TFT DT. The first switching TFT ST1 includes a gate electrode receiving the gate signal SCAN, a drain electrode receiving the data voltage Vdata of the data line DL and a source electrode connected to the first node N1. The first switching TFT ST1 operates more sensitively than the other TFTs in the subpixel SP. As a result, it is desirable or needed to increase a threshold voltage of the first switching TFT ST1 for easy control.

The second switching TFT ST2 switches a current between the second node N2 and the sensing voltage readout line SRL in response to the sensing signal SEN of a sensing line SL to store the source voltage of the second node N2 in a sensing capacitor Cx of the sensing voltage readout line SRL. When the display panel PAN is driven, the second switching TFT ST2 resets the source voltage of the driving TFT DT as an initialization voltage (Vpre) by switching the current between the second node N2 and the sensing voltage readout line SRL in response to the sensing signal SEN. The second switching transistor TFT ST2 includes a gate electrode connected to the sensing line SL, a drain electrode connected to the second node N2 and a source electrode connected to the sensing voltage readout line SRL.

Although the pixel circuit of the subpixel SP has a 3TIC structure including three TFTs and one storage capacitor in the first embodiment, it is not limited thereto and can have other structures. For example, the pixel circuit of the subpixel SP can have one of 4TIC, 5TIC, 6TIC, 7TIC and 8TIC structures in other examples.

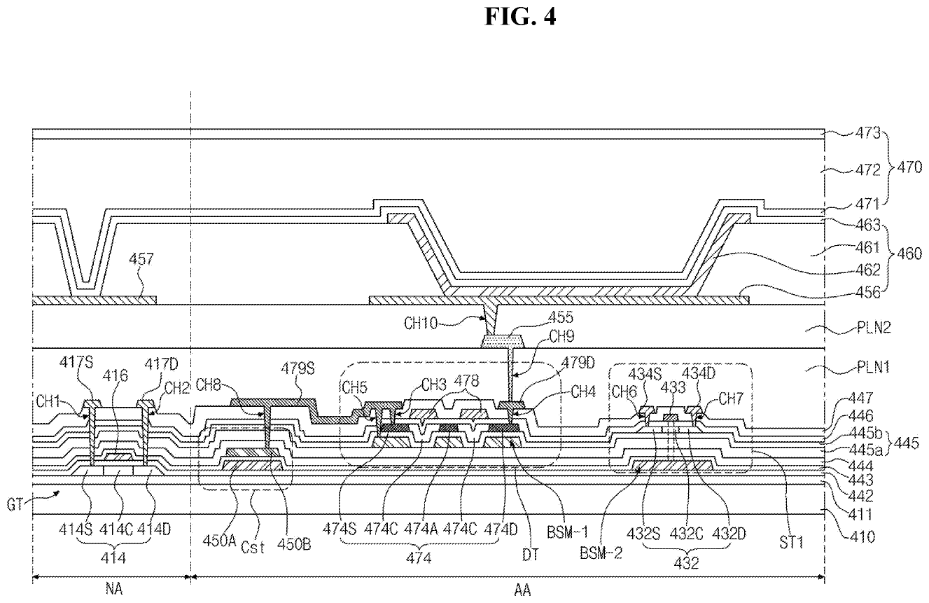

FIG. 4 is a cross-sectional view showing the display device according to the first embodiment of the present disclosure. Particularly, FIG. 4 shows an example of a gate driving TFT GT having a polycrystalline semiconductor pattern in the gate driving unit (e.g., the gate driving unit 130 of FIG. 1) of the non-display area NA, the driving TFT DT having an oxide semiconductor pattern and driving an emitting element 460 (e.g., emitting element D of FIG. 3) in the subpixel SP of the display area AA, and the first switching TFT ST1 having an oxide semiconductor pattern and the storage capacitor Cst. Each or some of the subpixels SP in the display panel PAN can have the configuration shown in FIGS. 3 and/or 4, but can have other circuit configurations.

Referring to FIG. 4, the driving TFT DT and the first switching TFT ST1 are disposed in the subpixel SP on a substrate 410. Although the driving TFT DT and the first switching TFT ST1 are shown as examples in the subpixel SP of FIG. 4, a plurality of switching TFTs can be disposed in the subpixel on the substrate 410.

A plurality of gate driving TFTs GT constituting the gate driving unit can be disposed in the gate driving unit of the non-display area NA. The gate driving TFT GT can use a polycrystalline semiconductor pattern as an active layer in the first embodiment. In another embodiment, the gate driving TFT GT can use an oxide semiconductor pattern as an active layer as in the first switching TFT ST1.

Although the gate driving TFT GT having the active layer of a polycrystalline semiconductor pattern is disposed in the non-display area NA in the first embodiment, a switching TFT having the same structure as the gate driving TFT GT can be disposed in the subpixel SP of the display area in another embodiment.

The gate driving TFT GT in the non-display area NA and the switching TFT (e.g., the first switching TFT ST1) in the display area AA can have different types due to different impurities. For example, the gate driving TFT GT and the switching TFT can be a negative (N) type and a positive (P) type, respectively, or a P type and a N type, respectively.

In another embodiment, the plurality of gate driving TFTs in the gate driving unit can have a complementary metal oxide semiconductor (CMOS) structure including a TFT having a polycrystalline semiconductor pattern as an active layer and a TFT having an oxide semiconductor pattern as an active layer.

The gate driving TFT having a polycrystalline semiconductor pattern as an active layer is exemplarily disposed in the non-display area NA in the first embodiment.

The gate driving TFT GT includes a polycrystalline semiconductor pattern 414 on a lower buffer layer 411 over the substrate 410, a first gate insulating layer 442 on the polycrystalline semiconductor pattern 414, a first gate electrode 416 on the first gate insulating layer 442 and overlapping the polycrystalline semiconductor pattern 414, a plurality of insulating layers on the first gate electrode 416, and a first source electrode 417S and a first drain electrode 417D on the plurality of insulating layers.

The substrate 410 can have a multiple layer where an organic layer and an inorganic layer are alternately laminated. For example, the substrate 410 can include an organic layer such as polyimide and an inorganic layer such as silicon oxide (SiO2) alternately laminated.

The lower buffer layer 411 is disposed on the substrate 410. The lower buffer layer 411 blocks moisture penetrating from an exterior. The lower buffer layer 411 can include at least one layer of an inorganic insulating material such as silicon oxide (SiO2).

The polycrystalline semiconductor pattern 414 is disposed on the lower buffer layer 411. The polycrystalline semiconductor pattern 414 is used as an active layer of a TFT. The polycrystalline semiconductor pattern 414 includes a first channel region 414C as well as a first source region 414S and a first drain region 414D at both sides of the first channel region 414C.

The first gate insulating layer 442 is disposed on the polycrystalline semiconductor pattern 414 over the entire substrate 410. The first gate insulating layer 442 can have at least one layer of an inorganic insulating material such as silicon oxide (SiO2). The first gate insulating layer 442 protects and insulates the polycrystalline semiconductor pattern 414 from an exterior.

The first gate electrode 416 is disposed on the first gate insulating layer 442 to overlap the first channel region 414C of the polycrystalline semiconductor pattern 414.

The first gate electrode 416 can include a metallic material. For example, the first gate electrode 416 can have a single layer or a multiple layer including one of molybdenum (Mo), aluminum (Al), chromium (Cr), gold (Au), titanium (Ti), nickel (Ni), neodymium (Nd) and copper (Cu) or an alloy thereof. The embodiments of the present disclosure are not limited thereto.

The plurality of insulating layers can be disposed between the first gate electrode 416 and the first source electrode 417S and between the first gate electrode 416 and the first drain electrode 417D.

The plurality of insulating layers can include a first interlayer insulating layer 443 contacting a top surface of the first gate electrode 416 and a second interlayer insulating layer 444, an upper buffer layer 445, a second gate insulating layer 446 and a third interlayer insulating layer 447 sequentially disposed on the first interlayer insulating layer 443.

The first source electrode 417S and the first drain electrode 417D are disposed on the third interlayer insulating layer 447. The first source electrode 417S and the first drain electrode 417D are connected to the polycrystalline semiconductor pattern 414 through a first contact hole CH1 and a second contact hole CH2, respectively. The first contact hole CH1 and the second contact hole CH2 are formed in the first gate insulating layer 442, the first interlayer insulating layer 443, the second interlayer insulating layer 444, the upper buffer layer 445, the second gate insulating layer 446 and the third interlayer insulating layer 447 to expose the first source region 414S and the first drain region 414D, respectively, of the polycrystalline semiconductor pattern 414.

The driving TFT DT, the firs switching TFT ST1 and the storage capacitor Cst are disposed in the subpixel SP of the display area AA.

In the first embodiment, the driving TFT DT and the first switching TFT ST1 use an oxide semiconductor pattern as an active layer.

The driving TFT DT includes a first oxide semiconductor pattern 474, a second gate electrode 478 overlapping the first oxide semiconductor pattern 474, a second source electrode 479S and a second drain electrode 479D.

The oxide semiconductor pattern can include an oxide of a metallic material such as zinc (Zn), indium (In), gallium (Ga), tin (Sn) and titanium (Ti) and a combination thereof. For example, the oxide semiconductor pattern can include zinc oxide (ZnO), zinc tin oxide (ZTO), zinc indium oxide (ZIO), indium oxide (InO), titanium oxide (TiO), indium gallium zinc oxide (IGZO) and indium zinc tin oxide (IZTO).

A driving TFT can use a polycrystalline semiconductor pattern having an advantage in a relatively high speed operation as an active layer. However, a driving TFT having a polycrystalline semiconductor pattern can have a leakage current in an off state and a power can be consumed due to the leakage current. Specifically, the leakage current in an off state can cause a more serious issue in a relatively low speed operation where a display device displays a static image such as a text.

As a result, the driving TFT DT of the first embodiment of the present disclosure uses an oxide semiconductor pattern having an advantage of blocking a leakage current as an active layer.

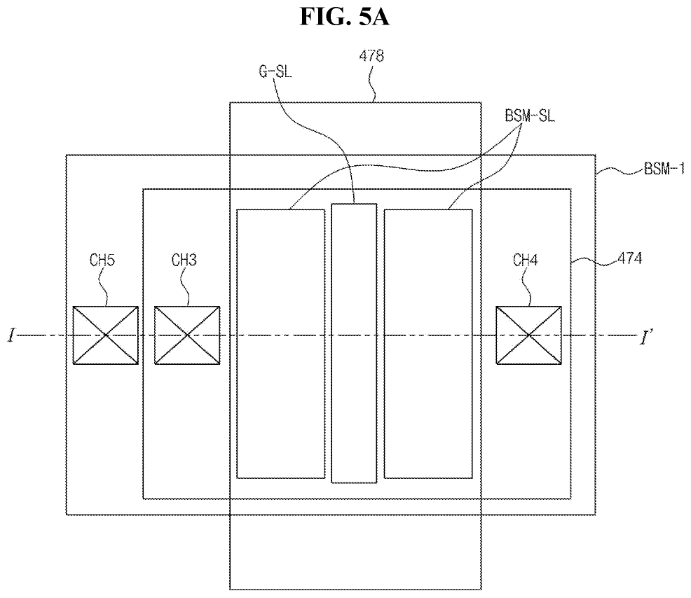

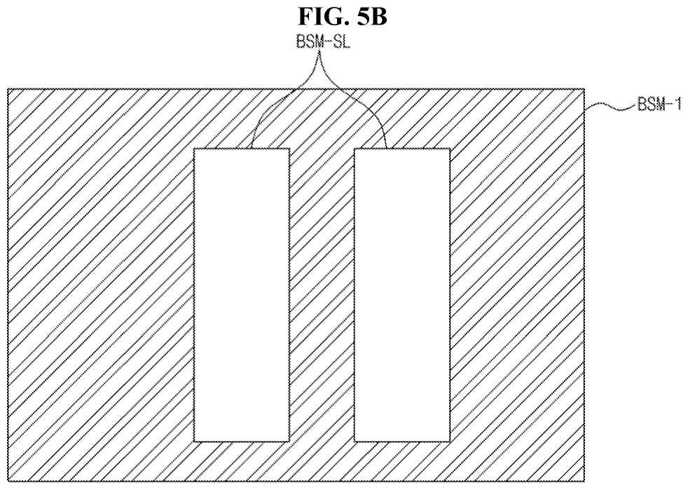

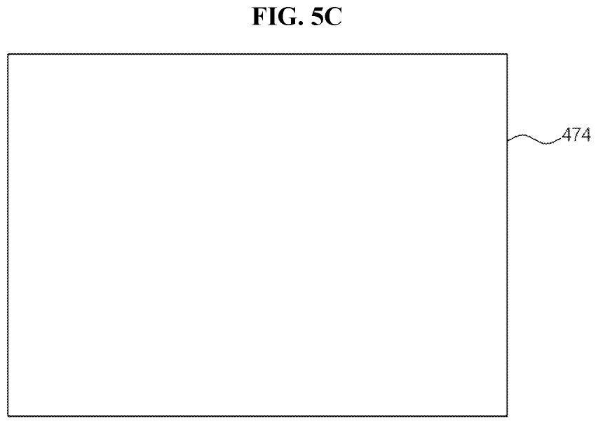

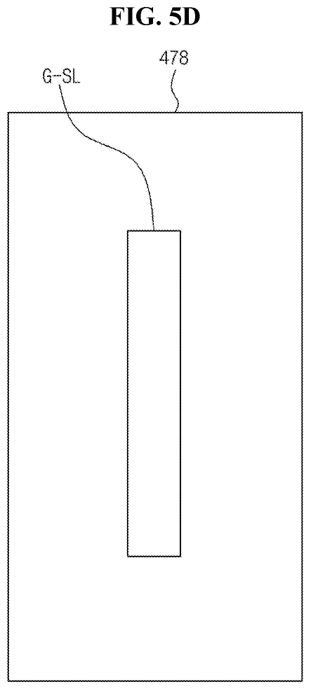

When the TFT uses an oxide semiconductor pattern as an active layer, a current change with respect to a voltage change is relatively great due to a property of an oxide semiconductor material but deterioration can occur in a low gray level range where an accurate current control is needed. Accordingly, in the first embodiment, the driving TFT DT has a structure where a change value in a current with respect to a change value in a voltage applied to a gate electrode is relatively insensitive, which will be discussed in more detail now referring to FIGS. 5A-6B.

FIG. 5A is a plan view showing an example of a driving thin film transistor of the display device according to the first embodiment of the present disclosure, and FIGS. 5B to 5D are plan views showing material layers of the driving thin film transistor of FIG. 5A. FIG. 6A is a cross-sectional view taken along a line I-I′ of FIG. 5A, and FIG. 6B is a circuit diagram showing an example of the parasitic capacitances of the driving thin film transistor of FIG. 6A. The driving thin film transistor of FIG. 5A can be the driving TFT DT of the present disclosure discussed above.

Referring to FIGS. 4 to 5D, the driving TFT DT includes the first oxide semiconductor pattern 474 on the upper buffer layer 445, the second gate insulating layer 446 covering the first oxide semiconductor pattern 474, the second gate electrode 478 on the second gate insulating layer 446 and overlapping the first oxide semiconductor pattern 474, and the second source electrode 479S and the second drain electrode 479D on the third interlayer insulating layer 447 over the second gate electrode 478. The second gate electrode 478, the second source electrode 479S and the second drain electrode 479D can have the same layer as each other.

The first oxide semiconductor pattern 474 as an active layer includes a second channel region 474C and a second source region 474S and a second drain region 474D at both sides of the second channel region 474C. The second source region 474S and the second drain region 474D are conductorized (“conductized”) semiconductor regions adjacent to the second channel region 474C.

A first lower conductive pattern BSM-1 is disposed under the first oxide semiconductor pattern 474. The first lower conductive pattern BSM-1 can capture a hydrogen particle injected from a lower portion of the first oxide semiconductor pattern 474 to protect the first oxide semiconductor pattern 474 from the hydrogen particle. When the hydrogen particle is injected into the oxide semiconductor pattern, the hydrogen particle combines with a vacancy that functions as a carrier of the oxide semiconductor pattern, which can deteriorate a reliability of the oxide semiconductor pattern.

The first lower conductive pattern BSM-1 can include first slits BSM-SL so that a top surface thereof has at least one uneven pattern. A region of the first lower conductive pattern BSM-1 corresponding to the first oxide semiconductor pattern 474 can be enlarged due to the first slits BSM-SL. Here, the slits can also be referred to as thru-holes.

In FIG. 6A, the first lower conductive pattern BSM-1 includes at least one first slit BSM-SL so that a cross-section of the first lower conductive pattern BSM-1 has at least one uneven pattern. The first slits BSM-SL of the first lower conductive pattern BSM-1 can be a hole of a rectangular shape passing through the first lower conductive pattern BSM-1.

The first lower conductive pattern BSM-1 can form a relatively great step difference (large step difference) along a top surface thereof due to the first slits BSM-SL.

In FIGS. 5B and 6A, the first lower conductive pattern BSM-1 has a relatively great step difference (large step difference) on a top surface thereof due to the first slits BSM-SL.

A thickness of the first lower conductive pattern BSM-1 is needed to be greater than a thickness of the first oxide semiconductor pattern 474. For example, when the thickness of the first oxide semiconductor pattern 474 is within a range of about 100 Å to 500 Å, the thickness of the first lower conductive pattern BSM-1 can be equal to or greater than ten times of the thickness of the first oxide semiconductor pattern 474. Aa a result, the thickness of the first lower conductive pattern BSM-1 can be equal to or greater than about 1000 Å. For example, the thickness of the first lower conductive pattern BSM-1 can be within a range of about 2000 Å to 5000 Å.

A second sub-upper buffer layer 445b is disposed on the first lower conductive pattern BSM-1 having the first slits BSM-SL.

Since the second sub-upper buffer layer 445b is formed along a top surface of the first lower conductive pattern BSM-1 having a step difference due to the first slits BSM-SL, the second sub-upper buffer layer 445b also has a step difference on a top surface thereof.

In FIG. 5C, the first oxide semiconductor pattern 474 is disposed on the second sub-upper buffer layer 445b. Since the first oxide semiconductor pattern 474 is disposed on the second sub-upper buffer layer 445b having a step difference on a top surface thereof, the first oxide semiconductor pattern 474 extends toward and dips towards the substrate 410 in a space formed by the first slits BSM-SL. For instance, the channel region 474C of the first oxide semiconductor pattern 474 is bent one or more time, so that its portion is disposed between two adjacent parts of the first lower conductive pattern BSM-1. As a result, an area of the first oxide semiconductor pattern 474 and an area of the first lower conductive pattern BSM-1 facing each other are enlarged.

In FIG. 5D, the second gate insulating layer 446 is disposed on the first oxide semiconductor pattern 474, and the second gate electrode 478 is disposed on the second gate insulating layer 446.

In FIGS. 5D and 6A, the second gate electrode 478 can include a second slit G-SL. The second slit G-SL can be disposed between the first slits BSM-SL in a plan view.

When the first oxide semiconductor pattern 474 is doped with an impurity over the second gate electrode 478, the second gate electrode 478 functions as a doping mask. As a result, a region of the first oxide semiconductor pattern 474 covered with the second gate electrode 478 becomes a channel region, and a region including the second slit G-SL not covered with the second gate electrode 478 becomes a conductorized region.

In FIG. 6A, the conductorized region includes the second source region 474S, the second drain region 474D and the middle conductorized region 474A. The channel region of the first oxide semiconductor pattern 474 can be the second channel region 474C.

The first lower conductive pattern BSM-1 is disposed on a first sub-upper buffer layer 445a, and the first lower conductive pattern BSM-1 can include at least one first slit BSM-SL therein.

The first lower conductive pattern BSM-1 can be a conductive metallic pattern or a conductorized semiconductor pattern. The first lower conductive pattern BSM-1 can be a metallic pattern including titanium (Ti) capturing a hydrogen particle for protecting the first oxide semiconductor pattern 474 from a hydrogen particle penetrating from a lower portion of the first oxide semiconductor pattern 474. For example, the first lower conductive pattern BSM-1 can have a single layer of titanium (Ti) or an alloy of molybdenum (Mo) and titanium (Ti) or a multiple layer of molybdenum (Mo) and titanium (Ti). It is not limited thereto, and the first lower conductive pattern BSM-1 can include another metallic layer including titanium (Ti).

The first slit BSM-SL can be a hole having a rectangular shape penetrating the first lower conductive pattern BSM-1. The first lower conductive pattern BSM-1 can have a step difference at a top surface thereof due to the first slit BSM-SL.

The thickness of the first lower conductive pattern BSM-1 can be equal to or greater than about 1000 Å. For example, the thickness of the first lower conductive pattern BSM-1 can be within a range of about 2000 Å to about 5000 Å. As a result, a height of the step difference due to the first slit BSM-SL can be the same as the thickness of the first lower conductive pattern BSM-1.

The first lower conductive pattern BSM-1 can be disposed under the first oxide semiconductor pattern 474 to completely overlap the first oxide semiconductor pattern 474.

A second sub-upper buffer layer 445b is disposed on the first lower conductive pattern BSM-1. As a result, the second sub-upper buffer layer 445b is disposed along a space by the first slit BSM-SL to form a step difference. The first oxide semiconductor pattern 474 is disposed on the second sub-upper buffer layer 445b.

The first oxide semiconductor pattern 474 extends along the space defined by the first slit BSM-SL and dips towards the substrate 410, and is disposed on the second sub-upper buffer layer 445b.

The first oxide semiconductor pattern 474 includes the conductorized region doped with an impurity and the channel region. The conductorized region includes the second source region 474S, the second drain region 474D and the middle conductorized region 474A.

At least one middle conductorized region 474A can be disposed between the second source region 474S and the second drain region 474D.

The second gate insulating layer 446 is disposed on the first oxide semiconductor pattern 474, and the second gate electrode 478 is disposed on the second gate insulating layer 446.

The conductorized region (e.g., 474A, 474S, 474D, etc.) is formed by doping the first oxide semiconductor pattern 474 with an impurity using the second gate electrode 478 as a doping mask. As a result, a region of the first oxide semiconductor pattern 474 not covered with the second gate electrode 478 becomes the conductorized region.

The conductorized region includes the second source region 474S connected to the second source electrode 479S, the second drain region 474D connected to the second drain electrode 479D, and the middle conductorized region 474A between the second source region 474S and the second drain region 474D.

In FIG. 6A, two second channel regions 474C are formed in the first oxide semiconductor pattern 474.

Since the second channel regions 474C extend and dip towards the substrate 410 in the space defined by the first slit BSM-SL, a length of each second channel region 474C can be elongated. Further, since each second channel region 474C is formed in the space defined by the first slit BSM-SL, an area of the second channel region 474C corresponding to the first lower conductive pattern BSM-1 is enlarged. As a result, a parasitic capacitance Cbuf (FIG. 6B) between the second channel region 474C and the first lower conductive pattern BSM-1 increases.

In addition, since the second channel region 474C is divided by the middle conductorized region 474A (or two channel regions 474C separated by the middle conductorized region 474A is provided), a resistance reduction effect is provided such that a carrier through a channel is reduced by a resistance.

Although one middle conductorized region 474A is disposed in the first oxide semiconductor pattern 474 and the second channel region 474C is divided into two parts in the first embodiment of FIG. 6A, one or more middle conductorized regions 474A can be disposed in the first oxide semiconductor pattern 474 in another embodiment.

When the first oxide semiconductor pattern 474 has a thickness of several hundreds angstroms (Å), the first oxide semiconductor pattern 474 can have a length of several micrometers (μm), and one or more second channel regions 474C can be disposed in the first oxide semiconductor pattern 474.

To dispose a plurality of second channel regions 474C in the first oxide semiconductor pattern 474, the second gate electrode 478 used as a doping mask in a doping step of an impurity can have at least one second slit G-SL.

In FIG. 5D, the second slit G-SL can be a slit having a rectangular shape penetrating the second gate electrode 478 of a metallic pattern.

In FIG. 6A, the second slit G-SL corresponds to the middle conductorized region 474A, and the second slit G-SL can be disposed between the second channel regions 474C in a plan view.

The second gate electrode 478 including the second slit G-SL is disposed on the second gate insulating layer 446, and the second gate electrode 478 is insulated by the third interlayer insulating layer 447.

The second source electrode 479S and the second drain electrode 479D are disposed on the third interlayer insulating layer 447. The second source electrode 479S and the second drain electrode 479D are connected to the second source region 474S and the second drain region 474D through a third contact hole CH3 and a fourth contact hole CH4, respectively.

The second source electrode 479S is electrically connected to the first lower conductive pattern BSM-1 through a fifth contact hole CH5.

When the second source electrode 479S is electrically connected to the first lower conductive pattern BSM-1, the following advantageous effects can be obtained by the present disclosure, which will be discussed referring to FIG. 6B.

Referring to FIG. 6B, since the second source region 474S and the second drain region 474D of the first oxide semiconductor pattern 474 are conductorized, a first parasitic capacitance Cact is generated in the first oxide semiconductor pattern 474 during an on/off operation. Further, a second parasitic capacitance Cgi is generated between the second gate electrode 478 and the first oxide semiconductor pattern 474. In addition, a third parasitic capacitance Cbuf is generated between the first lower conductive pattern BSM-1 electrically connected to the second source electrode 479S and the channel region of the first oxide semiconductor pattern 474.

Since the first oxide semiconductor pattern 474 and the first lower conductive pattern BSM-1 are electrically connected to each other by the second source electrode 479S, the first parasitic capacitance Cact and the third parasitic capacitance Cbuf are connected to each other in parallel, and the first parasitic capacitance Cact and the second parasitic capacitance Cgi are connected to each other in series. When the gate voltage Vgat is applied to the second gate electrode 478, an effective voltage Veff applied to the first oxide semiconductor pattern 474 is obtained according to the following Equation 1.

$$Δ Veff = ( Cgi * Δ Vgat ) / ( Cgi + Cbuf + Cact ) \qquad [ Equation 1 ]$$

As a result, since the effective voltage Veff applied to the second channel region 474C is inversely proportional to the third parasitic capacitance Cbuf, the effective voltage Veff applied to the first oxide semiconductor pattern 474 can be adjusted by changing the third parasitic capacitance Cbuf. The capacitance is inversely proportional to the distance and proportional to the area.

When the third parasitic capacitance Cbuf increases by disposing the first lower conductive pattern BSM-1 adjacent to the channel region of the first oxide semiconductor pattern 474, a real current value flowing through the first oxide semiconductor pattern 474 can be reduced.

When the area where the first lower conductive pattern BSM-1 and the channel region of the first oxide semiconductor pattern 474 face into each other is enlarged, the third parasitic capacitance Cbuf can increase.

The second parasitic capacitance Cgi can be adjusted by changing a distance between the second gate electrode 478 and the channel region of the first oxide semiconductor pattern 474. The second parasitic capacitance Cgi decreases when the distance between the second gate electrode 478 and the channel region of the first oxide semiconductor pattern 474 increases, and the second parasitic capacitance Cgi increases when the distance between the second gate electrode 478 and the channel region of the first oxide semiconductor pattern 474 decreases.

When the effective current flowing through the first oxide semiconductor pattern 474 is reduced, an s-factor increases and a control range of the driving TFT DT due to the gate voltage Vgat applied to the second gate electrode 478 is expanded.

When the second source electrode 479S of the driving TFT DT is electrically connected to the first lower conductive pattern BSM-1 (e.g., via the fifth contact hole CH5), the area where the first lower conductive pattern BSM-1 and the channel region of the first oxide semiconductor pattern 474 face into each other is enlarged, and the first lower conductive pattern BSM-1 is disposed adjacent to the first oxide semiconductor pattern 474, the emitting element 460 can be accurately controlled even in the low gray level range. As a result, a limitation such as an image stain which may occur in a low gray level range can be solved or addressed effectively by the present disclosure.

The third parasitic capacitance Cbuf can be adjusted through a first factor enlarging the area where the first lower conductive pattern BSM-1 and the channel region of the first oxide semiconductor pattern 474 face into each other, a second factor disposing the first lower conductive pattern BSM-1 adjacent to the first oxide semiconductor pattern 474, or a combination of the first and second factors. As a result, the s-factor of the driving TFT DT can be adjusted.

Accordingly, the third parasitic capacitance Cbuf between the channel region of the first oxide semiconductor pattern 474 and the first lower conductive pattern BSM-1 can be greater than the second parasitic capacitance Cgi between the second gate electrode 478 and the channel region of the first oxide semiconductor pattern 474.

An s-factor is a reciprocal value of a current change amount with respect to a gate voltage change amount during an on/off transition period of a thin film transistor. The s-factor can be an inverse value of a slope of a characteristic curve of a drain current with respect to a gate voltage (VI curve).

When the s-factor is relatively small, the slope of the characteristic curve of a drain current with respect to a gate voltage is relatively large, and the thin film transistor is turned on even by a relatively small gate voltage. As a result, a switching property of the thin film transistor is improved. However, since the gate voltage reaches a threshold voltage within a relatively short time, it can be challenging to display sufficient gray levels.

When the s-factor is relatively great, the slope of the characteristic curve of a drain current with respect to a gate voltage is relatively small, and an on/off response speed of the thin film transistor is reduced. As a result, a switching property of the thin film transistor can be affected; however, since the gate voltage reaches a threshold voltage within a relatively long time, it is possible to display sufficient gray levels.

Specifically, to adjust the third parasitic capacitance Cbuf, the first lower conductive pattern BSM-1 is inserted into the upper buffer layer 445 (e.g., between the upper buffer layers 445a and 445b), or the first lower conductive pattern BSM-1 has the first slit BSM-SL. As a result, the area where the first lower conductive pattern BSM-1 and the channel region of the first oxide semiconductor pattern 474 face into each other is enlarged.

Further, since the length of the first oxide semiconductor pattern 474 is relatively large as compared with the thickness of the first oxide semiconductor pattern 474, a voltage drop while a charge moves through the channel region can be reduced by dividing the channel region.

The third interlayer insulating layer 447 is disposed on the second gate electrode 478 of the driving TFT DT, and the second source electrode 479S and the second drain electrode 479D are disposed on the third interlayer insulating layer 447.

Returning to FIG. 4, the first switching TFT ST1 includes a second oxide semiconductor pattern 432, a third gate electrode 433, a third source electrode 434S and a third drain electrode 434D.

The second oxide semiconductor pattern 432 includes a third channel region 432C and a third source region 432S and a third drain region 432D at both sides of the third channel region 432C. The third source region 432S and the third drain region 432D are disposed adjacent to the third channel region 432C.

The second gate insulating layer 446 is disposed on the second oxide semiconductor pattern 432, and the third gate electrode 433 is disposed on the second gate insulating layer 446 over the second oxide semiconductor pattern 432.

The third source electrode 434S and the third drain electrode 434D can have the same layer as the second source electrode 479S and the second drain electrode 479D. The second source and drain electrodes 479S and 479D and the third source and drain electrodes 434S and 434D can be disposed on the third interlayer insulating layer 447.

A second lower conductive pattern BSM-2 is disposed under the second oxide semiconductor pattern 432. The second lower conductive pattern BSM-2 can block a hydrogen particle injected from a lower portion of the second oxide semiconductor pattern 432. The second lower conductive pattern BSM-2 can be a metallic pattern including titanium (Ti) as the first lower conductive pattern BSM-1.

The second lower conductive pattern BSM-2 can be disposed on the first gate insulating layer 442 together with the first gate electrode 416.

The third gate electrode 433 and the second lower conductive pattern BSM-2 can be electrically connected to each other to constitute a dual gate.

In FIG. 3, when the first switching TFT ST1 is a sampling transistor connected to the gate electrode of the driving TFT DT, the first switching TFT ST1 can perform a high speed on/off operation by connecting the third gate electrode 433 and the second lower conductive pattern BSM-2 to constitute a dual gate.

Referring back to FIG. 4, the subpixel SP includes the storage capacitor Cst.

The storage capacitor Cst stores the data voltage applied through the data line and supplies the data voltage to the emitting element 460.

The storage capacitor Cst includes two electrodes and a dielectric layer between the two electrodes. For example, the storage capacitor Cst can include a first capacitor electrode 450A having the same material and the same layer as the first gate electrode 416, and a second capacitor electrode 450B facing and overlapping the first capacitor electrode 450A.

The first interlayer insulating layer 443 can be disposed between the first capacitor electrode 450A and the second capacitor electrode 450B.

The second capacitor electrode 450B can be electrically connected to the second source electrode 479S through an eighth contact hole CH8.

Since the first capacitor electrode 450A has the same layer as the first gate electrode 416 and the second lower conductive pattern BSM-2, a mask process can be simplified.

Further, a first planarizing layer PLN1 is disposed on the driving TFT DT and the first switching TFT ST1 over the entire substrate 410. The first planarizing layer PLN1 can include an organic material such as photoacryl or can have a multiple layer of an inorganic layer and an organic layer. A connecting electrode 455 is disposed on the first planarizing layer PLN1. The connecting electrode 455 is electrically connected to the driving TFT DT through a ninth contact hole CH9 in the first planarizing layer PLN1 to connect the driving TFT DT with an anode 456 of the emitting element 460.

A conductive layer being formed of the same layer as the connecting electrode 455 can constitute a portion of various link lines in a bending area BA.

A second planarizing layer PLN2 can be disposed on the connecting electrode 455. The second planarizing layer PLN2 can include an organic material such as photoacryl or can have a multiple layer of an inorganic layer and an organic layer.

The anode 456 is disposed on the second planarizing layer PLN2. The anode 456 is electrically connected to the connecting electrode 455 through a tenth contact hole CH10 in the second planarizing layer PLN2.

The anode 456 can have a single layer or a multiple layer of a metallic material such as calcium (Ca), barium (Ba), magnesium (Mg), aluminum (Al), silver (Ag) and an alloy thereof. The anode 456 is connected to the second drain electrode 479D of the diving TFT DT to receive a voltage corresponding to an image signal.

A cathode connecting electrode 457 electrically connecting the low level voltage EVSS and a cathode 463 of the emitting element 460 can be disposed in the non-display area NA together with the anode 456. The cathode 463 is disposed both in the display area AA and the non-display area NA.

A bank layer 461 is disposed on the second planarizing layer PLN2. The bank layer 461 is a sidewall which divides the subpixel SP to prevent mixture of colored lights emitted from the adjacent subpixels SP.

An emitting layer 462 of the emitting element 460 is disposed on a top surface of the anode 456 and a slanting surface of the bank layer 461. The emitting layer 462 is disposed in each subpixel SP. For example, the emitting layer 462 can include and can be one of a red emitting layer for emitting a red colored light, a green emitting layer for emitting a green colored light and a blue emitting layer for emitting a blue colored light. Alternatively, the emitting layer 462 can include and can be one of a white emitting layer for emitting a white colored light.

The emitting layer 462 can include an electron injecting layer for injecting an electron, an electron transporting layer for transporting an electron, an emitting material layer for emitting a light, a hole transporting layer for transporting a hole, and a hole injecting layer for injecting a hole. Other structures can be used for the emitting layer 462.

The cathode 463 is disposed on the emitting layer 462. The cathode 463 can include a transparent conductive material such as indium tin oxide (ITO) and indium zinc oxide (IZO) or a metallic material having a thin thickness transmitting a visible ray. It is not limited thereto.

An encapsulating layer 470 is disposed on the cathode 463. The encapsulating layer 470 can have a single layer of an inorganic layer, a double layer of an inorganic layer and an organic layer, or a triple layer of an inorganic layer, an organic layer and an inorganic layer. The inorganic layer can include an inorganic material such as silicon nitride (SiNx) and silicon oxide (SiOx), and it is not limited thereto. The organic layer can have an organic material such as polyethylene terephthalate (PET), polyethylene naphthalate (PEN), polycarbonate (PC), polyimide (PI), polyethersulfone (PES), polyoxymethylene (POS), polyarylate (PAR) and a mixture thereof, and it is not limited thereto.

In the example of FIG. 4, the encapsulating layer 470 can exemplarily have a triple layer composed of a first inorganic layer 471, an organic layer 472 and a second inorganic layer 473, which can extend both in the display area AA and the non-display area NA.

A cover glass can be disposed on the encapsulating layer 470 to be attached to the encapsulating layer 470 using an adhesive. The adhesive can include a material having an excellent thermal resistance and an excellent water resistance. For example, the adhesive can include a heat curable resin such as an epoxy compound, an acrylate compound and an acrylic rubber. The adhesive can include a light curable resin which is cured by irradiating a light such as an ultraviolet ray.

The adhesive can attach the substrate 410 and the cover glass and can function as an encapsulating layer blocking a moisture of an exterior.

The cover glass can be an encapsulating cap for encapsulating the display device 100. For example, a protecting film such as a polystyrene (PS) film, a polyethylene (PE) film, a polyethylene naphthalate (PEN) film and a polyimide (PI) film can be used as the cover glass, or a glass can be used as the cover glass.

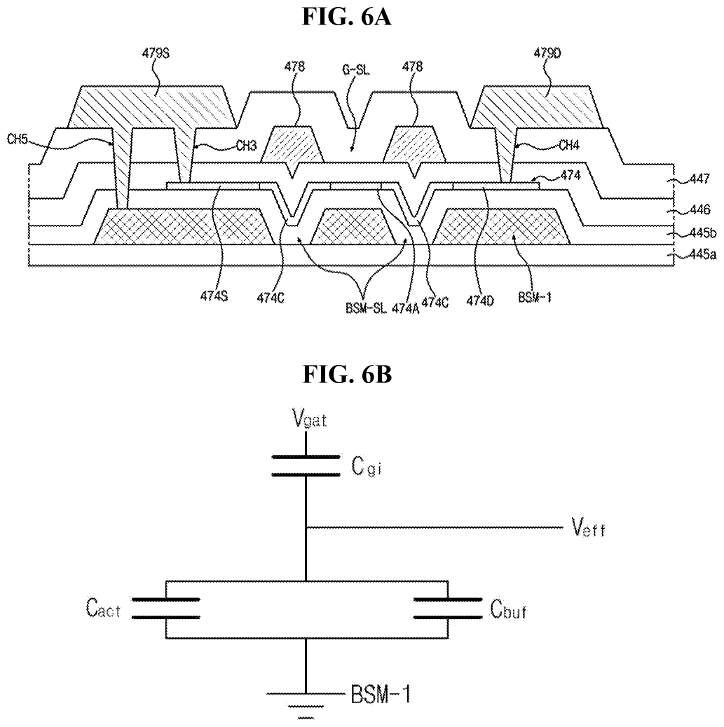

Although the first lower conductive pattern BSM-1 has the first slit BSM-SL to form a step difference on a top surface thereof in the first embodiment, the first lower conductive pattern BSM-1 can have a trench (e.g., BSM-T in FIG. 7 to be discussed below) to form a step difference on a top surface thereof in another embodiment. Differently from the first slit BSM-SL, the trench BSM-T can be a groove (or indentation) having a rectangular shape not penetrating completely through the first lower conductive pattern BSM-1 (e.g., not a thru-hole like the slits BSM_SL), and a lower portion of the first lower conductive pattern BSM-1 can be closed.

FIG. 7 is a cross-sectional view showing a driving thin film transistor of a display device according to the second embodiment of the present disclosure. The driving thin film transistor of FIG. 7 has some same or similar features as that shown in FIG. 6, but has trenches BSM-T instead of the first slits BSM-SL among the differences.

Referring to FIG. 7, a first lower conductive pattern BSM-1 has at least two trenches BSM-T, and a second gate electrode 478 does not have a slit (no G-SL). As a result, a second channel region 474C of a driving TFT DT is not divided. In another embodiment, the second gate electrode 478 can have a second slit G-SL therein and a first oxide semiconductor pattern 474 can have at least two channel regions. Illustration and/or description of the parts that are the same as that of the first embodiment will be omitted or may be briefly provided.

When the first lower conductive pattern BSM-1 has a trench instead of a slit as shown in FIG. 7 according to the second embodiment, the following additional advantages can be obtained.

The first lower conductive pattern BSM-1 can capture a hydrogen particle injected from a lower portion of the first oxide semiconductor pattern 474. However, when the first lower conductive pattern BSM-1 completely blocks the lower portion of the first oxide semiconductor pattern 474, the first lower conductive pattern BSM-1 can prevent an external light from being irradiated onto the second channel region 474C.

When the external light is irradiated onto the channel region of the first oxide semiconductor pattern 474, a reliability of the driving TFT DT can be affected or deteriorated. As a result, in the display device according to the second embodiment of the present disclosure, the external light is shielded and the reliability of the driving TFT DT is further improved by forming a trench instead of a slit in the first lower conductive pattern BSM-1.

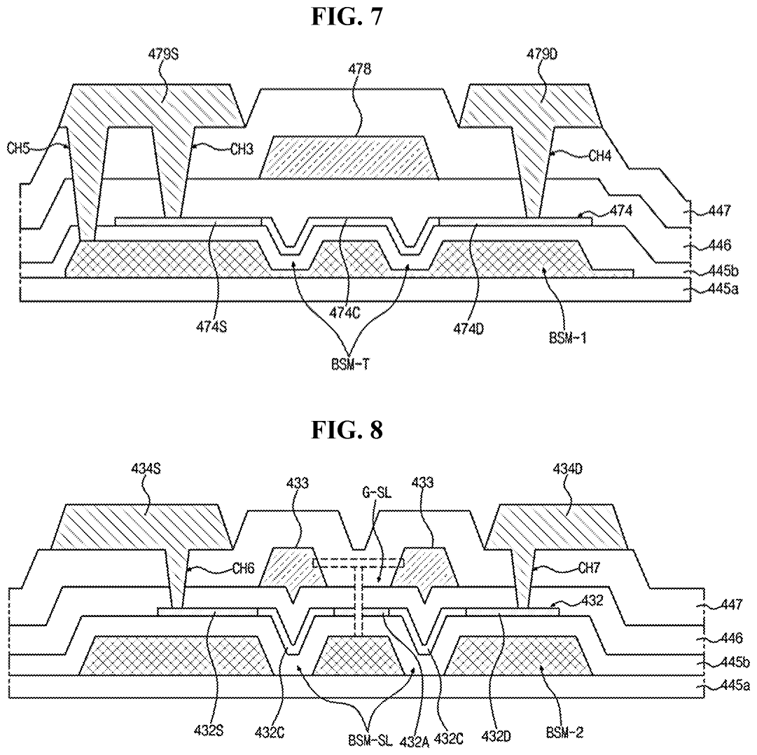

In another embodiment, the first switching TFT ST1 has an increased threshold voltage, which is now discussed referring to FIG. 8. For instance, FIG. 8 shows another example of the first switching TFT (ST1) of FIG. 4.

Particularly, FIG. 8 is a cross-sectional view showing a first switching thin film transistor of a display device according to a third embodiment of the present disclosure.

Referring to FIG. 8, a first switching TFT ST1 includes a second oxide semiconductor pattern 432, a second lower conductive pattern BSM-2 under the second oxide semiconductor pattern 432 and overlapping the second oxide semiconductor pattern 432, a third gate electrode 433 over the second oxide semiconductor pattern 432 and overlapping the second oxide semiconductor pattern 432, and a third source electrode 434S and a third drain electrode 434D connected to the second oxide semiconductor pattern 432.

The second lower conductive pattern BSM-2 can include at least one first slit BSM-SL therein. At least two first slits BSM-SL can be disposed in the second lower conductive pattern BSM-2 as in the first embodiment.

The second oxide semiconductor pattern 432 includes a third source region 432S and a third drain region 432D that are conductorized by doping with an impurity and a second middle conductorized region 432A between the third source region 432S and the third drain region 432D. The second oxide semiconductor pattern 432 can include a third channel region 432C between the third source region 432S and the third drain region 432D. The third channel region 432C can have a divided structure.

The second oxide semiconductor pattern 432 can have the same structure as that of the first embodiment of the present disclosure.

As a result, the third channel region 432C can extend and dip toward the substrate 410 in a space defined by the first slit BSM-SL of the second lower conductive pattern BSM-2. As a result, the area where the third channel region 432C and the second lower conductive pattern BSM-2 face into each other is enlarged.

The third gate electrode 433 can include a second slit G-SL therein. The second slit G-SL can be disposed to correspond to the second middle conductorized region 432A of the second oxide semiconductor pattern 432. The third gate electrode 433 can be disposed to correspond to the third channel region 432C.

The third gate electrode 433 functions as a doping mask during a doping process for forming a conductorized region in the second oxide semiconductor pattern 432. As a result, at least one second slit G-SL can be formed in the third gate electrode 433 to divide the third channel region 432C into a plurality.

The third gate electrode 433 and the second lower conductive pattern BSM-2 can be electrically connected to each other to constitute a dual gate. When the first switching TFT ST1 is formed to have a dual gate, the first switching TFT ST1 can perform a high speed operation.

The third source electrode 434S and the third drain electrode 434D are electrically connected to the third source region 432S and the third drain region 432D, respectively.

The second lower conductive pattern BSM-2 can be disposed on the first sub-upper buffer layer 445a as the first lower conductive pattern BSM-1. The first lower conductive pattern BSM-1 and the second lower conductive pattern BSM-2 can have the same material and the same layer as each other. As a result, since the second lower conductive pattern BSM-2 is disposed adjacent to (or closer to) the third channel region 432C of the second oxide semiconductor pattern 432, a parasitic capacitance Cbuf between the second lower conductive pattern BSM-2 and the third channel region 432C of the second oxide semiconductor pattern 432 can be increased.

When the first switching TFT ST1 is a sampling transistor, the first switching TFT ST1 is turned on once during one frame. The first switching TFT ST1 is turned on during a relatively short time period and is turned off during the other time period due to a negative voltage. As a result, the first switching TFT ST1 can have a negative bias temperature stress (NBTS) state which may be an unstable state due to application of a negative voltage, and a threshold voltage of the first switching TFT ST1 can be reduced. To address this issue, in the display device according to the third embodiment of the present disclosure, the threshold voltage of the first switching TFT ST1 can be increased due to a dual gate.

In FIG. 8, since the third gate electrode 433 and the second lower conductive pattern BSM-2 are electrically connected to each other to constitute a dual gate, a second parasitic capacitance Cgi between the second oxide semiconductor pattern 432 and the third gate electrode 433 and a third parasitic capacitance Cbuf between the second oxide semiconductor pattern 432 and the second lower conductive pattern BSM-2 are connected to each other in parallel. When the second parasitic capacitance Cgi and the third parasitic capacitance Cbuf increase, the threshold voltage of the first switching TFT ST1 increases.

In the display device according to the third embodiment of the present disclosure, to increase the threshold voltage of the first switching TFT ST1, the area where the second lower conductive pattern BSM-2 and the third channel region 432C of the second oxide semiconductor pattern 432 face into each other increases due to the slit in the second lower conductive pattern BSM-2. Further, the third parasitic capacitance Cbuf between the second lower conductive pattern BSM-2 and the second oxide semiconductor pattern 432 is adjusted by controlling a vertical distance between the second lower conductive pattern BSM-2 and the second oxide semiconductor pattern 432.

To increase the threshold voltage of the first switching TFT ST1, the area where the second lower conductive pattern BSM-2 and the third channel region 432C of the second oxide semiconductor pattern 432 face into each other increases, and the vertical distance between the second lower conductive pattern BSM-2 and the second oxide semiconductor pattern 432 decreases.

Consequently, in the display device according to one or more embodiments of the present disclosure, since the driving TFT and the switching TFT having the oxide semiconductor pattern are disposed in the subpixel, the leakage current in the off state is reduced and the power consumption is reduced. Further, since the driving TFT has the relatively large s-factor, the gray levels are accurately displayed in the low gray level range. In addition, the threshold voltage of the driving TFT increases. Moreover, since the plurality of switching TFTs in the subpixel have the different threshold voltages, the plurality of switching TFTs perform the different functions properly.

### Example Embodiments of the Present Disclosure can Also be Described as Follows

According to an example embodiment of a present disclosure, a display device includes a substrate having a display area and a non-display area at a periphery of the display area; a first thin film transistor in the display area, the first thin film transistor including a first semiconductor pattern, a first gate electrode, a first source electrode and a first drain electrode; an emitting element in the display area, the emitting element connected to the first thin film transistor; and a first lower conductive pattern under the first semiconductor pattern, the first lower conductive pattern overlapping with the first semiconductor pattern and having a plurality of uneven patterns on a top surface thereof, wherein the first lower conductive pattern is connected to one of the first source electrode and the first drain electrode.

In some example embodiments, the display device further includes a second thin film transistor in the display area, the second thin film transistor including a second semiconductor pattern having a same material as the first semiconductor pattern, a second gate electrode on the second semiconductor pattern, a second source electrode connected to the second semiconductor pattern and a second drain electrode connected to the second semiconductor pattern; and a second lower conductive pattern under the second semiconductor pattern, the second lower conductive pattern overlapping with the second semiconductor pattern and having a plurality of uneven patterns on a top surface thereof, and the second lower conductive pattern is electrically connected to the second gate electrode.

In some example embodiments, the display device further includes a third thin film transistor in the non-display area, the third thin film transistor including a third semiconductor pattern, a third gate electrode on the third semiconductor pattern, a third source electrode connected to the third semiconductor pattern and a third drain electrode connected to the third semiconductor pattern; and a third lower conductive pattern under the third semiconductor pattern, the third lower conductive pattern overlapping with the third semiconductor pattern and having a plurality of uneven patterns on a top surface thereof, and the third lower conductive pattern is electrically connected to the third gate electrode.

In some example embodiments, a buffer layer is disposed between the first semiconductor pattern and the first lower conductive pattern, a first gate insulating layer is disposed between the first semiconductor pattern and the first gate electrode, and a parasitic capacitance between the first semiconductor pattern and the first lower conductive pattern is greater than a parasitic capacitance between the first semiconductor pattern and the first gate electrode.

In some example embodiments, the display device further includes a third thin film transistor in the non-display area, the third thin film transistor including a third semiconductor pattern, a third gate electrode on the third semiconductor pattern, a third source electrode connected to the third semiconductor pattern and a third drain electrode connected to the third semiconductor pattern; and a third lower conductive pattern under the third semiconductor pattern, the third lower conductive pattern overlapping with the third semiconductor pattern and having a plurality of uneven patterns on a top surface thereof, and the third lower conductive pattern is electrically connected to the third gate electrode.

In some example embodiments, the first semiconductor pattern and the second semiconductor pattern include an oxide semiconductor material, and the first thin film transistor is a driving thin film transistor driving a subpixel in the display area.

In some example embodiments, a buffer layer is disposed between the first semiconductor pattern and the first lower conductive pattern, a first gate insulating layer is disposed between the first semiconductor pattern and the first gate electrode, and a parasitic capacitance between the first semiconductor pattern and the first lower conductive pattern is greater than a parasitic capacitance between the first semiconductor pattern and the first gate electrode.

In some example embodiments, an area where the first lower conductive pattern and an active region of the first semiconductor pattern face into each other is greater than an area where the active region of the first semiconductor pattern and the first gate electrode face into each other.

In some example embodiments, the first lower conductive pattern is disposed to be closer to the first semiconductor pattern than the first gate electrode.

In some example embodiments, one of the first lower conductive pattern, the second lower conductive pattern and the third lower conductive pattern has at least one slit or at least one trench.

In some embodiments, the at least one slit or the at least one trench is disposed to correspond to a channel region of one of the first semiconductor pattern, the second semiconductor pattern and the third semiconductor pattern.

In some example embodiments, the channel region of one of the first semiconductor pattern, the second semiconductor pattern and the third semiconductor pattern extends toward the at least one slit or the at least one trench.

In some example embodiments, at least one of the first gate electrode, the second gate electrode and the third gate electrode has at least one slit therein.

In some example embodiments, each of the first semiconductor pattern, the second semiconductor pattern and the third semiconductor pattern includes at least two active regions separated from each other, and the at least one slit is disposed between the at least two active regions.

In some example embodiments, the display device further includes a third thin film transistor in the non-display area, the third thin film transistor including a third semiconductor pattern, a third gate electrode on the third semiconductor pattern, a third source electrode connected to the third semiconductor pattern and a third drain electrode connected to the third semiconductor pattern, and the third semiconductor pattern includes a polycrystalline semiconductor pattern in a layer different from the first semiconductor pattern.

According to another example embodiment of the present disclosure, an array substrate for a display device includes a substrate having a display area and a non-display area at a periphery of the display area; a buffer layer on the substrate; a first semiconductor pattern on the buffer layer; a first gate electrode over the first semiconductor pattern, the first gate electrode overlapping the first semiconductor pattern; a first source electrode and a first drain electrode over the first semiconductor pattern, the first source electrode and the first drain electrode electrically connected to the first semiconductor pattern; and a lower conductive pattern under the first semiconductor pattern, the buffer layer disposed between the lower conductive pattern and the first semiconductor pattern and the lower conductive pattern having a plurality of uneven patterns on a top surface thereof, wherein the lower conductive pattern is electrically connected to the first semiconductor pattern.

In some example embodiments, the first semiconductor pattern includes an oxide semiconductor material, and the lower conductive pattern has at least one slit or at least one trench.

In some example embodiments, the lower conductive pattern has a step difference due to the at least one slit or the at least one trench, and the first semiconductor pattern is bent along the step difference to extend toward the at least one slit or the at least one trench.

In some example embodiments, the array substrate further includes a driving thin film transistor driving a subpixel in the display area, the first semiconductor pattern, the first gate electrode, the first source electrode and the first drain electrode constitute a first thin film transistor, and the first thin film transistor is a switching thin film transistor connected to a gate electrode of the driving thin film transistor.

In some example embodiments, the first semiconductor pattern includes at least two active regions separated from each other.

In some example embodiments, the first gate electrode has at least one slit therein, and the at least one slit is disposed between the at least two active regions.

In some embodiments, a display device can include a display area including a plurality of subpixels disposed on a substrate, wherein one of the plurality of subpixels includes a driving thin film transistor, wherein the driving thin film transistor includes a lower conductive pattern disposed on the substrate, and including at least one slit or trench and two adjacent parts created by the at least one slit or trench, an insulating layer disposed on the at least one slit or trench of the lower conductive pattern, a semiconductor pattern disposed on the insulating layer, and including a source region, a drain region and a channel region disposed between the source and drain regions, and a gate electrode disposed on the semiconductor pattern, and wherein the channel region of the semiconductor pattern is bent so that a portion of the channel region is disposed between the two adjacent parts of the lower conductive pattern.

It will be apparent to those skilled in the art that various modifications and variation can be made in the present disclosure without departing from the scope of the disclosure. Thus, it is intended that the present disclosure cover the modifications and variations of this disclosure, provided they come within the scope of the appended claims and their equivalents.

What is claimed is:

1. A display device, comprising:
a display area and a non-display area adjacent to the display area disposed on a substrate;
a first thin film transistor disposed in the display area, the first thin film transistor including a first semiconductor pattern, a first gate electrode, a first source electrode and a first drain electrode;
an emitting element disposed in the display area, the emitting element connected to the first thin film transistor; and
a first lower conductive pattern disposed under the first semiconductor pattern, the first lower conductive pattern overlapping with the first semiconductor pattern and having at least one uneven pattern on a top surface thereof,
wherein the first lower conductive pattern is connected to one of the first source electrode and the first drain electrode.

2. The display device of claim 1, further comprising:
a second thin film transistor disposed in the display area, the second thin film transistor including a second semiconductor pattern having a same material as the first semiconductor pattern, a second gate electrode on the second semiconductor pattern, a second source electrode connected to the second semiconductor pattern, and a second drain electrode connected to the second semiconductor pattern; and
a second lower conductive pattern under the second semiconductor pattern, the second lower conductive pattern overlapping with the second semiconductor pattern and having at least one uneven pattern on a top surface thereof,
wherein the second lower conductive pattern is electrically connected to the second gate electrode.

3. The display device of claim 2, further comprising:
a third thin film transistor disposed in the non-display area, the third thin film transistor including a third semiconductor pattern, a third gate electrode on the third semiconductor pattern, a third source electrode connected to the third semiconductor pattern, and a third drain electrode connected to the third semiconductor pattern; and
a third lower conductive pattern disposed under the third semiconductor pattern, the third lower conductive pattern overlapping with the third semiconductor pattern and having at least one uneven pattern on a top surface thereof,
wherein the third lower conductive pattern is electrically connected to the third gate electrode.

4. The display device of claim 2, wherein at least one of the first semiconductor pattern and the second semiconductor pattern includes an oxide semiconductor material, and
the first thin film transistor is a driving thin film transistor configured to drive a subpixel in the display area.

5. The display device of claim 1, further comprising:
a buffer layer disposed between the first semiconductor pattern and the first lower conductive pattern; and
a first gate insulating layer disposed between the first semiconductor pattern and the first gate electrode,
wherein a parasitic capacitance between the first semiconductor pattern and the first lower conductive pattern is greater than a parasitic capacitance between the first semiconductor pattern and the first gate electrode.

6. The display device of claim 5, wherein an area where the first lower conductive pattern and an active region of the first semiconductor pattern face each other is greater in size than an area where the active region of the first semiconductor pattern and the first gate electrode face each other.

7. The display device of claim 5, wherein the first lower conductive pattern is disposed to be closer to the first semiconductor pattern than the first gate electrode.

8. The display device of claim 3, wherein one of the first lower conductive pattern, the second lower conductive pattern and the third lower conductive pattern has at least one slit or at least one trench being different from the at least one slit.

9. The display device of claim 8, wherein the at least one slit or the at least one trench is disposed to correspond to a channel region of one of the first semiconductor pattern, the second semiconductor pattern and the third semiconductor pattern.

10. The display device of claim 9, wherein the channel region of one of the first semiconductor pattern, the second semiconductor pattern and the third semiconductor pattern is shaped to extend toward the at least one slit or the at least one trench.

11. The display device of claim 3, wherein at least one of the first gate electrode, the second gate electrode and the third gate electrode has at least one slit therein.

12. The display device of claim 11, wherein each of the first semiconductor pattern, the second semiconductor pattern and the third semiconductor pattern includes at least two active regions separated from each other, and the at least one slit is disposed between the at least two active regions.

13. The display device of claim 2, further comprising:
a third thin film transistor disposed in the non-display area, the third thin film transistor including a third semiconductor pattern, a third gate electrode on the third semiconductor pattern, a third source electrode connected to the third semiconductor pattern, and a third drain electrode connected to the third semiconductor pattern,
wherein the third semiconductor pattern includes a polycrystalline semiconductor pattern disposed in a layer different from a layer of the first semiconductor pattern.

14. An array substrate for a display device, the array substrate comprising:
a display area and a non-display area adjacent to the display area disposed on a substrate;
a first semiconductor pattern disposed on the substrate;
a first gate electrode disposed on the first semiconductor pattern, the first gate electrode overlapping the first semiconductor pattern;
a first source electrode and a first drain electrode disposed on the first semiconductor pattern, wherein one of the first source electrode and the first drain electrode is electrically connected to the first semiconductor pattern; and
a lower conductive pattern disposed under the first semiconductor pattern,
wherein the lower conductive pattern has a plurality of uneven patterns on a top surface thereof, and
wherein the lower conductive pattern is electrically connected to the first semiconductor pattern.

15. The array substrate of claim 14, wherein the first semiconductor pattern includes an oxide semiconductor material, and the lower conductive pattern has at least one slit or at least one trench being different from the at least one slit.

16. The array substrate of claim 15, wherein the lower conductive pattern has a step difference due to the at least one slit or the at least one trench, and
the first semiconductor pattern is bent along the step difference to extend toward the at least one slit or the at least one trench.

17. The array substrate of claim 15, further comprising:
a driving thin film transistor configured to drive a subpixel in the display area,
wherein the first semiconductor pattern, the first gate electrode, the first source electrode and the first drain electrode constitute a first thin film transistor, and the first thin film transistor is a switching thin film transistor connected to a gate electrode of the driving thin film transistor.

18. The array substrate of claim 14, wherein the first semiconductor pattern includes at least two active regions separated from each other.

19. The array substrate of claim 18, wherein the first gate electrode has at least one slit therein, and the at least one slit is disposed between the at least two active regions.

20. A display device, comprising:
a display area including a plurality of subpixels disposed on a substrate,
wherein one of the plurality of subpixels includes a driving thin film transistor,
wherein the driving thin film transistor includes:
a lower conductive pattern disposed on the substrate, and including at least one slit or trench and two adjacent parts created by the at least one slit or trench,
an insulating layer disposed on the at least one slit or trench of the lower conductive pattern,
a semiconductor pattern disposed on the insulating layer, and including a source region, a drain region and a channel region disposed between the source and drain regions, and
a gate electrode disposed on the semiconductor pattern, and
wherein the channel region of the semiconductor pattern is bent so that a portion of the channel region is disposed between the two adjacent parts of the lower conductive pattern.

21. The display device of claim 20, wherein the portion of the channel region is disposed lower than a top surface of the two adjacent parts of the lower conductive pattern.

22. The display device of claim 20, wherein the channel region is separated into multiple channel regions,
the gate electrode is separated into multiple gate electrode parts, and
each of the gate electrode parts is disposed to correspond with one of the separated channel regions.

23. The display device of claim 20, wherein the gate electrode covers the entire channel region.

24. The display device of claim 20, wherein the at least one slit is a thru-hole, and the at least one trench is an indentation.
